(19) United States
(12) Patent Application Publication
(10) Pub. No.: US 2015/0014702 A1
(43) Pub. Date: Jan. 15, 2015

(54) LIGHT-EMITTING DIODE HAVING IMPROVED LIGHT EXTRACTION EFFICIENCY AND METHOD FOR MANUFACTURING SAME

(71) Applicant: Seoul Viosys Co., Ltd., Ansan-si (KR)

(72) Inventors: Jin Woong Lee, Ansan-si (KR); Kyoung Wan Kim, Ansan-si (KR); Yeo Jin Yoon, Ansan-si (KR); Sang Hyun Oh, Ansan-si (KR); Tae Gyun Kim, Ansan-si (KR)

(21) Appl. No.: 14/383,470

(22) PCT Filed: Feb. 26, 2013
(86) PCT No.: PCT/KR2013/001519

§ 371 Date: Sep. 5, 2014

(30) Foreign Application Priority Data
Mar. 7, 2012 (KR) 1020120023516

(51) Int. Cl. H01L 33/22; H01L 33/00; H01L 33/32

(52) U.S. Cl. CPC H01L 33/22; H01L 33/32; H01L 33/0075; H01L 2933/0058
USPC 257/76; 438/29

(57) ABSTRACT

Disclosed are a light-emitting diode having improved light extraction efficiency and a method for manufacturing same. This light-emitting diode includes: a gallium nitride substrate having an upper surface and a lower surface; and a gallium nitride semiconductor multilayer structure disposed on the lower surface of the substrate, and having a first conductive semiconductor layer, an active layer, and a second conductive semiconductor layer. Herein, the gallium nitride substrate has a main pattern having a protruding portion and a concave portion on the upper surface, and a rough surface formed on the protruding portion of the main pattern. The light-emitting diode is capable of improving light extraction efficiency through the upper surface thereof since the rough surface is formed along with the main pattern on the upper surface of the gallium nitride substrate.

### TECHNICAL FIELD

The present invention relates to a light emitting diode and a method for manufacturing the same, and more particularly, to a light emitting diode having improved light extraction efficiency and a method of manufacturing the same.

### BACKGROUND ART

Generally, light emitting diodes are manufactured by growing gallium nitride (GaN) semiconductor layers on a sapphire substrate. However, the sapphire substrate and the GaN semiconductor layer have significant differences in terms of coefficient of thermal expansion and lattice constant. Thus, crystal defects such as threading dislocation frequently occur within the grown GaN layer. The crystal defects make it difficult to improve electrical and optical properties of the light emitting diodes.

In order to solve these problems, attempts have been made to use a GaN substrate as a growth substrate. Since the GaN substrate and a GaN layer grown thereon are formed of a homogeneous material, the GaN layer having good crystal quality can be grown.

However, the GaN substrate has higher refractive index than the sapphire substrate, thereby causing significant light loss due to the total internal reflection when light is generated in the active layer.

### DISCLOSURE

### Technical Problem

The present invention is aimed at providing a light emitting diode capable of reducing light loss in a substrate while improving light extraction efficiency, and a method for manufacturing the same.

In addition, the present invention is aimed at providing a light emitting diode suitable for a flip-chip structure using a GaN substrate, and a method for manufacturing the same.

### Technical Solution

In accordance with one aspect of the present invention, a light emitting diode comprises: a gallium nitride substrate having an upper surface and a lower surface; and a gallium nitride semiconductor stack structure disposed on the lower surface of the substrate, and including a first conductive type semiconductor layer, a second conductive type semiconductor layer, and an active layer disposed between the first conductive type semiconductor layer and the second conductive type semiconductor layer. The gallium nitride substrate comprises: a main pattern having protrusions and depressions on the upper surface of the substrate; and rough surfaces formed on the protrusions of the main pattern.

Side surfaces of the gallium nitride substrate may comprise an inclined surface. The inclined surface may be inclined such that the gallium nitride substrate has a gradually increasing width from the upper surface to the lower surface thereof.

The inclined surfaces may extend from the upper surface of the gallium nitride substrate. In contrast, vertical side surfaces may extend from the upper surface of the gallium nitride substrate, and the inclined surface may extend from the vertical side surface. In addition, the side surfaces of the gallium nitride substrate may further comprise a vertical surface extending from the inclined surface.

In some embodiments, the depressions may have an acute V-shaped section. In other embodiments, inner walls of the depressions may be inclined at an angle of 85° to 90° with respect to the lower surface of the substrate, and the depressions may have a bottom surface. In this case, the gallium nitride substrate may further comprise rough surfaces formed on the depressions.

In accordance with another aspect of the present invention, a method of manufacturing a light emitting diode comprises: growing semiconductor layers on a gallium nitride substrate; forming a main pattern having protrusions and depressions by patterning a surface of the gallium nitride substrate opposite to the semiconductor layers; and forming rough surfaces on the protrusions by wet etching the surface of the gallium nitride substrate on which the main pattern is formed.

The semiconductor layers may comprise a first conductive type semiconductor layer, an active layer, and a second conductive type semiconductor layer. Here, the second conductive type semiconductor layer may be disposed farther away from the gallium nitride substrate than the first conductive type semiconductor layer, and the active layer may be disposed between the first conductive type semiconductor layer and the second conductive type semiconductor layer.

The method may further comprise forming inclined surfaces on the substrate by partially removing the substrate, after forming the rough surfaces. The inclined surfaces may be formed using a blade.

The method may further comprise forming a reflector on the semiconductor layers. The reflector may be formed on the second conductive type semiconductor layer.

Forming the main pattern may be performed using dry or wet etching. In particular, the wet etching may be performed using a mixed solution of H₂SO₄ and H₃PO₄. In addition, forming the rough surfaces may be performed using wet etching, and the wet etching may be performed using a boiling solution of KOH or NaOH. Further, the wet etching may be performed using an aqueous solution of deionized water, NaOH, and H₂O₂.

### Advantageous Effects

According to embodiments of the present invention, rough surfaces are formed together with a main pattern on an upper surface of a gallium nitride substrate, thereby enhancing light extraction efficiency through the upper surface of the substrate. In addition, the inclined surface is formed on the side surface of the substrate so that light loss caused by total internal reflection can be reduced. Further, a light emitting diode having a flip-chip structure is provided, making it possible to provide a light emitting diode with excellent heat dissipation characteristics.

### DESCRIPTION OF DRAWINGS

FIG. 1 is a sectional view of a light emitting diode according to one embodiment of the present invention.

FIG. 2 is a sectional view of a light emitting diode according to another embodiment of the present invention.

FIGS. 3 to 7 are sectional views showing a method of manufacturing a light emitting diode according to one embodiment of the present invention.

FIG. 8 is a sectional view of a blade used to manufacture a light emitting diode according to one embodiment of the present invention.

### BEST MODE

Hereinafter, embodiments of the present invention will be described in detail with reference to the accompanying drawings. The following embodiments are provided by way of examples so as to fully convey the spirit of the present invention to those skilled in the art. Accordingly, the present invention is not limited to the embodiments disclosed herein and may also be implemented in different forms. In the drawings, widths, lengths, thicknesses, and the like of elements may be exaggerated for convenience. Throughout the specification, like reference numerals denote like elements having the same or similar functions.

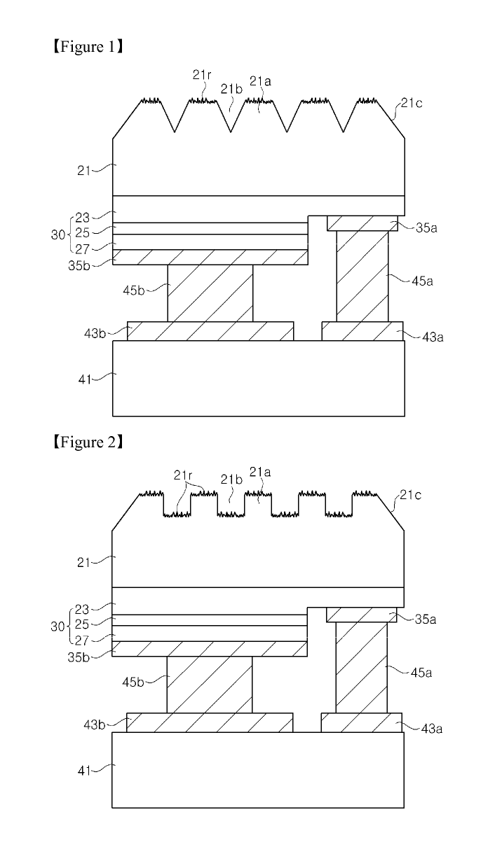

FIG. 1 is a sectional view of a light emitting diode according to one embodiment of the present invention.

Referring to FIG. 1, the light emitting diode includes a gallium nitride substrate 21 and a semiconductor stack structure 30, which includes a first conductive type semiconductor layer 23, an active layer 25, and a second conductive type semiconductor layer 27. In addition, the light emitting diode may include a first electrode 35a and a second electrode 35b. The light emitting diode may be bonded to first and second electrodes 43a, 43b on a sub-mount 41 through first and second bonding bumps 45a, 45b, respectively.

The gallium nitride substrate 21 includes an upper surface and a lower surface, and the semiconductor stack structure 30 is disposed on the lower surface of the substrate 21. The gallium nitride substrate 21 includes a main pattern with protrusions 21a and depressions 21b on the upper surface thereof, and rough surfaces formed on the protrusions 21a of the main pattern.

The gallium nitride substrate 21 may be formed on the upper surface thereof with the plural protrusions 21a, and each of the protrusions 21a may have a truncated conical shape, for example, a truncated circular cone or truncated pyramid shape. In this case, the depressions 21b are connected with each other in a mesh shape. In contrast, the protrusions 21a may be formed in a mesh shape, and the plural depressions 21b may be separated from each other by the protrusions 21a. As shown in FIG. 1, the depressions 21b may have an acute V shape. Due to the shape of the depressions 21b, total internal reflection can be prevented from occurring at the bottom of the depressions 21b.

The gallium nitride substrate 21 may have a thickness ranging from 250 μm to 300 μm, and the protrusions 21a may have an average height ranging from about 5 μm to about 20 μm. In addition, the rough surfaces on the protrusions 21a may have a surface roughness (Ra) from 0.1 μm to 1 μm.

In addition, side surfaces of the gallium nitride substrate 21 may include inclined surfaces 21c. The inclined surfaces 21c are inclined such that the substrate 21 has a gradually increasing width from the upper surface to the lower surface thereof. As shown in FIG. 1, the inclined surfaces 21c may extend from the upper surface of the gallium nitride substrate 21, without being limited thereto. That is, vertical side surfaces may extend from the upper surface of the gallium nitride substrate 21, and the inclined surfaces 21c may continuously extend from the vertical side surfaces. Further, the side surfaces of the gallium nitride substrate 21 may further include vertical side surfaces extending from the lower surface of the substrate 21, and the inclined surfaces 21c may extend from the vertical side surfaces.

When light generated from the active layer 25 is incident upon an upper surface of the substrate 21, the protrusions 21a, the depressions 21b, and the rough surfaces 21r can reduce total internal reflection of the light on the upper surface of the substrate 21, thereby increasing light extraction efficiency through the upper surface of the substrate 21. In addition, the inclined surfaces 21 can emit light which is generated in the active layer 25 and incident upon the side surfaces of the substrate 21, thereby further increasing light extraction efficiency. Here, although the inclined surfaces 21c may be inclined at the same slope as that of inner walls of the depressions 21b, the present invention is not limited thereto. Alternatively, the inclined surfaces 21c may be inclined at a slighter slope than that of the inner walls in order to improve direct emission of light from the side surfaces of the substrate.

The semiconductor stack structure 30 is disposed on the lower surface of the gallium nitride substrate 21. That is, the semiconductor stack structure 30 is disposed on the surface opposite to the upper surface of the substrate on which the protrusions 21a are formed. The semiconductor stack structure 30 includes the first conductive type semiconductor layer 23, the active layer 25, and the second conductive type semiconductor layer 27. The first conductive type semiconductor layer 23, the active layer 25, and the second conductive type semiconductor layer 27 may be formed of gallium nitride-based compound semiconductors, and the active layer 25 may have a single quantum well structure or a multi-quantum well structure. Here, the first conductive type and the second conductive type may be n type and p type semiconductor layers, respectively, or vice versa.

The semiconductor stack structure 30 may be composed of semiconductor layers grown on the gallium nitride substrate 21, and thus may have a dislocation density of about 5E6/cm² or less. Accordingly, a light emitting diode having excellent luminous efficiency and suitable for high current driving can be provided.

The second conductive type semiconductor layer 27 and the active layer 25 are disposed on a partial region of the first conductive type semiconductor layer 23, with other regions of the first conductive type semiconductor layer 23 exposed to the outside.

The first electrode 35a is formed on the exposed region of the first conductive type semiconductor layer 23. The first electrode 35a may be formed of a conductive material, for example Ti/Al, which makes ohmic contact with the first conductive type semiconductor layer 23. The second electrode 35b is formed on the second conductive type semiconductor layer 27 to make ohmic contact with the second conductive type semiconductor layer 27. In addition, the second electrode 35b may include a reflective layer such as Ag or Al to act as a reflector. Further, the second electrode 35b may also be formed as an omnidirectional reflector using a conductive material layer (ITO, FTO, GZO, ZnO, ZnS, InP, Si, or Si alloys) and a metal film (Au, Ag, Cu, Al, Pt, or alloys including at least one of Au, Ag, Cu, Al, and Pt).

The first and second bonding bumps 45a, 45b disposed on the first and second electrodes 35a, 35b may be bonded to the first and second electrodes 43a, 43b, respectively, on the sub-mount 41. Accordingly, the light emitting diode bonded to the sub-mount 41 by flip-chip bonding is provided.

FIG. 2 is a sectional view of a light emitting diode according to another embodiment of the present invention.

Referring to FIG. 2, the light emitting diode according to this embodiment is generally similar to the light emitting diode described above with reference to FIG. 1 except for depressions 21b. That is, in this embodiment, inner walls of the depressions 21b are inclined at a steeper slope than the inner walls of the depressions in the embodiment shown in FIG. 1 and, for example, may be inclined at an angle of 85° and 90° with respect to a lower surface of a substrate 21. Accordingly, in this embodiment, the depressions 21b have relatively horizontal bottom surfaces instead of acute V-shaped bottom surfaces. In addition, the depressions 21b has rough surfaces 21r on the bottom surfaces thereof.

According to this embodiment, the inner walls of the depressions 21b have a relatively steep slope, which makes it possible to reduce light loss within the protrusions 21a. In addition, the depressions 21b have the rough surfaces 21r formed on the bottom surfaces thereof, thereby preventing total internal reflection from occurring on the bottoms surfaces thereof.

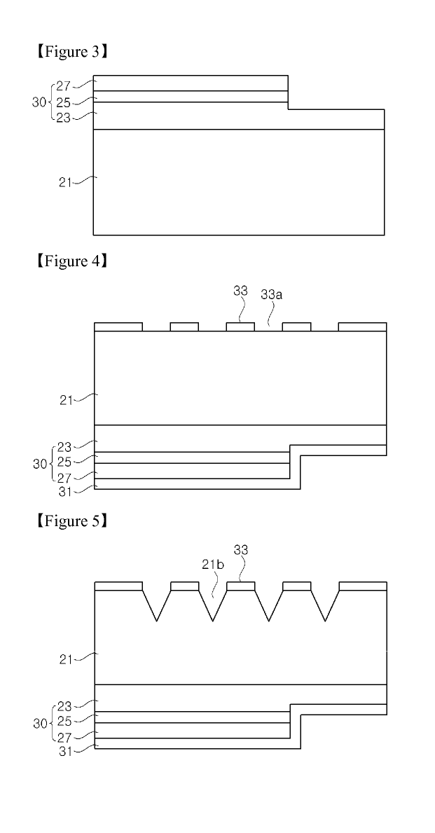

FIGS. 3 to 7 are sectional views showing a method of manufacturing a light emitting diode according to one embodiment of the present invention.

Referring to FIG. 3, a gallium nitride semiconductor stack structure 30 including a first conductive type semiconductor layer 23, an active layer 25, and a second conductive type semiconductor layer 27 is grown on a gallium nitride substrate 21. Then, the first conductive type semiconductor layer 23 may be exposed through mesa etching. The semiconductor layers 23, 25, 27 may be grown by MOCVD or MBE.

Referring to FIG. 4, an etching mask pattern 33 is formed on a surface of the substrate opposite to the semiconductor stack structure 30, namely, on an upper surface of the substrate 21. The etching mask pattern 33 may be formed in a mesh shape or an island shape and has openings 33a for exposing the lower surface of the substrate 21. The openings 33a or the islands may be arranged in a honeycomb pattern. However, the shape of the etching mask pattern 33 may be changed in various ways, and particularly, the openings 33a may have a variety of sizes instead of a constant size.

The etching mask pattern 33 may be formed by forming a mask layer, such as a silicon oxide film, on the lower surface of the substrate 21 and then partially removing the mask layer through photolithography and etching.

In addition, the semiconductor layers 23, 25, 27 may be covered with an etching mask layer 31. The etching mask layer 31 protects the semiconductor layers 23, 25, 27 in the course of wet etching, which will be described below, and may be formed of, for example, a silicon oxide layer.

Before the etching mask pattern 33 is formed, the upper surface of the substrate 21 may be flattened. The upper surface of the substrate 21 may be flattened by planarization through grinding, lapping, or polishing. In this embodiment, however, since the gallium nitride substrate 21 is soft compared with a sapphire substrate, the upper surface of the substrate 21 may be easily flattened only through mechanical polishing using a surface plate and diamond slurries. Generally, after planarization, the substrate 21 may have a thickness from about 250 μm to about 300 μm, and a portion removed from the substrate by planarization may have a thickness from about 20 μm to about 50 μm. In addition, the upper surface of the substrate may also be polished through chemical mechanical polishing (CMP).

Referring to FIG. 5, the upper surface of the substrate 21 is subjected to etching using the etching mask pattern 33 as a mask layer. Thus, depressions 21b corresponding to the openings 33a, and protrusions 21a relatively protruding with respect to the depressions 21b are formed. The upper surface of the gallium nitride substrate 21 may be subjected to dry etching or wet etching using an inductively coupled plasma apparatus. Wet etching may be performed using a mixed solution of sulfuric acid and phosphoric acid. In particular, when wet etching is used, the gallium nitride substrate 21 may be etched along a crystal face thereof, whereby the depressions 21a may be formed to have a V shape or a hexagonal pyramid shape.

Thereafter, the etching mask pattern 33 and the etching mask layer 1 may be removed using buffered oxide etchant (BOE).

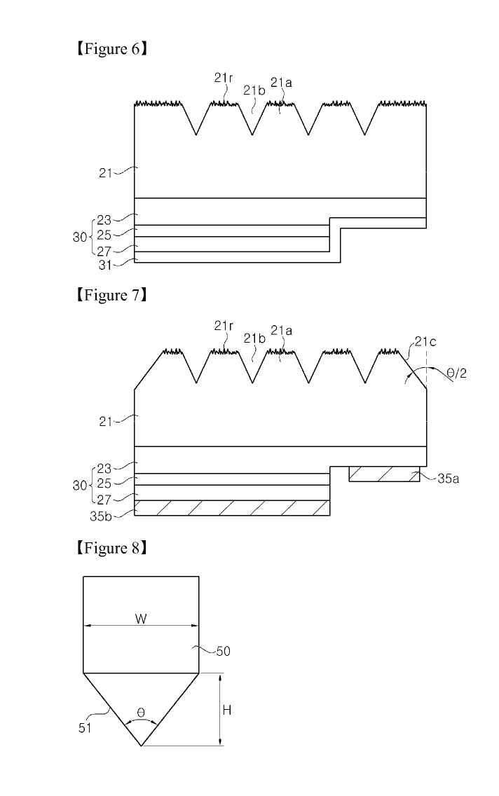

Referring to FIG. 6, after the etching mask pattern 33 is removed, rough surfaces 21r are formed on upper surfaces of the protrusions 21a. The rough surfaces 21r may be formed by wet etching. Wet etching may be performed using a boiling solution of KOH or NaOH. Further, wet etching may be performed using an aqueous solution of NaOH, H₂O₂, and deionized water. Accordingly, minute cones having a height from 0.1 μm to 1 μm may be formed on the upper surfaces of the protrusions 21a, thereby forming the rough surfaces 21r.

In the course of forming the rough surfaces 21r, the etching mask layer 31 may remain or another etching mask layer may be formed to protect the semiconductor layers 23, 25, and 27.

Referring to FIG. 7, after the etching mask layer 31 is removed, first and second electrodes 35a and 35b are formed on the first and second conductive type semiconductor layers 23 and 27, respectively. In addition, such bonding bumps 45a and 45b as shown in FIG. 1 may be formed on the first and second electrodes 35a and 35b, respectively. The second electrode 35b includes a reflective layer that reflects light generated from the active layer 25, and thus also acts as a reflector.

Thereafter, inclined surfaces 21c are formed on the substrate 21 by partially removing the upper surface of the substrate 21. The inclined surfaces 21c may be formed by scribing using a blade 50 as shown in FIG. 8. Then, the substrate 21 is divided into individual light emitting diodes, thereby providing completed light emitting diodes.

Referring to FIG. 8, the blade 50 has a body portion and a tip portion, which has inclined surfaces 51 formed on both sides thereof. The tip portion has a vertex angle θ and a height H, and the body portion has a width W. The inclined surfaces 21c shown in FIG. 7 are determined by the shape of the blade 50. For example, when the blade 50 has a large vertex angle (θ), the inclined surfaces 21c have a gentle slope, and when the blade 50 has a small vertex angle (θ), the inclined surfaces 21c have a steep slope. In addition, vertical side surfaces extending from the upper surface of the substrate 21 and the inclined surfaces 21c extending from the vertical side surfaces may be formed by adjusting the height (H) of the blade.

After the scribing process using the blade 50, the substrate 21 may be divided into individual light emitting diodes through a breaking process, and thus the substrate 21 includes side surfaces formed by the breaking process.

Although the depressions 21b have been illustrated as having a V-shape in this embodiment, depressions having relatively horizontal bottom surfaces may be formed by adjusting the size of the openings 33a formed using the etching mask pattern 33 or by dry etching, thereby manufacturing as light emitting diode, as shown in FIG. 2.

Although various embodiments and features of the present invention have been described above, the present invention is not limited thereto, and various changes and modifications can be made without departing from the spirit and the scope of the present invention.

1. A light emitting diode comprising:
a gallium nitride substrate having an upper surface and a lower surface; and
a gallium nitride semiconductor stack structure disposed on the lower surface of the substrate and comprising a first conductive type semiconductor layer, a second conductive type semiconductor layer, and an active layer disposed between the first conductive type semiconductor layer and the second conductive type semiconductor layer,
wherein the gallium nitride substrate comprises a main pattern having protrusions and depressions on the upper surface of the substrate, and rough surfaces formed on the protrusions of the main pattern.

2. The light emitting diode of claim 1, wherein a side surface of the gallium nitride substrate comprises an inclined surface, and the inclined surface is inclined such that the gallium nitride substrate has a gradually increasing width from the upper surface to the lower surface thereof.

3. The light emitting diode of claim 2, wherein the inclined surface extends from the upper surface of the gallium nitride substrate.

4. The light emitting diode of claim 2, wherein the side surface of the gallium nitride substrate further comprises a vertical surface extending from the inclined surfaces.

5. The light emitting diode of claim 1, further comprising:
a reflector disposed under the second conductive type semiconductor layer,
wherein the second conductive type semiconductor layer is disposed farther away from the substrate than the first conductive type semiconductor layer.

6. The light emitting diode of claim 1, wherein the protrusions are disposed on the upper surface of the gallium nitride substrate and have an average height of 5 μm to 20 μm.

7. The light emitting diode of claim 6, wherein the rough surfaces have a surface roughness (Ra) ranging from 0.1 μm to 1 μm.

8. The light emitting diode of claim 1, wherein inner walls of the depressions are inclined at an angle of 85° to 90° with respect to the lower surface of the substrate.

9. The light emitting diode of claim 8, wherein the gallium nitride substrate includes rough surfaces formed on the depressions.

10. The light emitting diode of claim 9, wherein the rough surfaces of the depressions have a surface roughness (Ra) ranging from 0.1 μm to 1 μm.

11. A method of manufacturing a light emitting diode, comprising:
growing semiconductor layers on a gallium nitride substrate;
forming a main pattern having protrusions and depressions by patterning a surface of the gallium nitride substrate opposite to the semiconductor layers; and
forming rough surfaces on the protrusions by wet etching the surface of the gallium nitride substrate on which the main pattern is formed.

12. The method of claim 11, further comprising:
after forming the rough surfaces, forming inclined surfaces on the substrate by partially removing the substrate.

13. The method of claim 12, wherein the inclined surfaces are formed using a blade.

14. The method of claim 12, further comprising:
forming a reflector on the semiconductor layers.

15. The method of claim 11, wherein the forming a main pattern is performed using dry or wet etching.

16. The method of claim 15, wherein the wet etching is performed using a mixed solution of sulfuric acid and phosphoric acid.

17. The method of claim 16, further comprising:
before performing the wet etching, forming an etching mask layer to protect the semiconductor layers.

18. The method of claim 11, wherein the forming of rough surfaces is performed using wet etching.

19. The method of claim 18, wherein the wet etching is performed using a boiling solution of KOH or NaOH.

20. The method of claim 18, wherein the wet etching is performed using an aqueous solution of deionized water, NaOH, and H₂O₂.
